(19) United States
(12) Patent Application Publication
(10) Pub. No.: US 2011/0210385 A1
(43) Pub. Date: Sep. 1, 2011

(54) Non-volatile Semiconductor Device, Programmable Memory, Capacitor and Metal Oxide Semiconductor

(75) Inventors: Chrong-Jung LIN, HSINCHU CITY (TW); Ya-Chin KING, TAIPEI CITY (TW)

(73) Assignees: Chrong-Jung LIN, HSINCHU CITY (TW); Ya-Chin KING, TAIPEI CITY (TW)

(21) Appl. No.: 12/975,067

(22) Filed: Dec. 21, 2010

(30) Foreign Application Priority Data
Dec. 21, 2009 (TW) 98143967

(51) Int. Cl. H01L 29/94

(52) U.S. Cl. 257/298; 257/296; 257/E29.345

(57) ABSTRACT

A non-volatile semiconductor device, a programmable memory device, a capacitor and a metal oxide semiconductor are disclosed, wherein the non-volatile semiconductor device includes a gate dielectric layer, a floating gate, a coupling gate, a source and a drain. The gate dielectric layer is formed on a semiconductor substrate. The floating gate is formed on the gate dielectric layer. The source and the drain are formed in the semiconductor substrate and are disposed at opposing sides of the floating gate. The coupling gate consists essentially of a capacitor dielectric layer and a contact plug, where the capacitor dielectric layer is formed on the floating gate, and the contact plug is formed on the capacitor dielectric layer.

### RELATED APPLICATIONS

This application claims priority to Taiwan Application Serial Number 98143967, filed Dec. 21, 2009, which is herein incorporated by reference.

### BACKGROUND

1.Technical Field

The present disclosure relates to electronic components, and more particularly, semiconductor components.

2. Description of Related Art

Since the invention of the integrated circuit, the semiconductor industry has experienced continued rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

In an attempt to further reduce the size of the electronic components and increase stability of the integrated circuit, there is an urgent need in the related field to provide novel electronic components.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one or more various aspects, the present disclosure is directed to a non-volatile semiconductor device, a programmable memory device, a capacitor and a metal oxide semiconductor. These novel electronic components have smaller size compared with the conventional components.

According to one embodiment of the present invention, a non-volatile semiconductor device includes a gate dielectric layer, a floating gate, a first source/drain, a second source/drain and a coupling gate. The gate dielectric layer is formed on a semiconductor substrate. The floating gate is formed on the gate dielectric layer. The first source/drain and the second source/drain are formed in the semiconductor substrate and disposed at opposing sides of the floating gate. The coupling gate consists essentially of a capacitor dielectric layer and a contact plug, wherein the capacitor dielectric layer is formed on the floating gate, and the contact plug is formed on the capacitor dielectric layer.

According to another embodiment of the present invention, a programmable memory device includes a gate dielectric layer, a polysilicon gate electrode, a first source/drain, a second source/drain and a coupling gate. The gate dielectric layer is formed on a semiconductor substrate. The polysilicon gate electrode is formed on the gate dielectric layer for receiving a voltage, so that a dielectric breakdown of the gate dielectric layer can result from the voltage for accessing data. The first source/drain and the second source/drain are formed in the semiconductor substrate and are separate from each other. The coupling gate consists essentially of a capacitor dielectric layer and a contact plug, wherein the capacitor dielectric layer is disposed on a portion of the semiconductor substrate, the portion of the semiconductor substrate is positioned between the first source/drain and the second source/drain, and the contact plug is formed on the capacitor dielectric layer.

According to yet another embodiment of the present invention, a capacitor compatible with semiconductor fabrication includes a bottom electrode, a capacitor dielectric layer and a top electrode. The bottom electrode is a heavily doped polysilicon layer or a heavily doped region of a semiconductor substrate. The capacitor dielectric layer is formed on the bottom electrode. The top electrode is formed on the capacitor dielectric layer, wherein the capacitor dielectric layer is a self-aligned silicide blocking layer or a resist protective layer.

According to another yet embodiment of the present invention, a metal oxide semiconductor compatible with semiconductor fabrication includes a capacitor dielectric layer, a contact plug, a first source/drain and a second source/drain. The capacitor dielectric layer is formed on a semiconductor substrate. The contact plug is formed on the capacitor dielectric layer. The first source/drain and the second source/drain are formed in the semiconductor substrate and disposed at opposing sides of the contact plug.

Many of the attendant features will be more readily appreciated, as the same becomes better understood by reference to the following detailed description considered in connection with the accompanying drawings.

### BRIEF DESCRIPTION OF THE DRAWINGS

The present description will be better understood from the following detailed description read in light of the accompanying drawing, wherein:

FIG. 1 is a cross-sectional view of a non-volatile semiconductor device according to one embodiment of the present disclosure;

FIG. 2 is a cross-sectional view of a non-volatile semiconductor device according to another embodiment of the present disclosure;

FIG. 3 is a cross-sectional view of a programmable memory device according to one embodiment of the present disclosure;

FIG. 4 is a cross-sectional view of a programmable memory device according to another embodiment of the present disclosure;

FIG. 5 is a cross-sectional view of a capacitor according to one embodiment of the present disclosure; and

FIG. 6 is a cross-sectional view of a metal oxide semiconductor according to one embodiment of the present disclosure.

### DETAILED DESCRIPTION

In the following detailed description, for purposes of explanation, numerous specific details are set forth in order to attain a thorough understanding of the disclosed embodiments. It will be apparent, however, that one or more embodiments may be practiced without these specific details. In other instances, well-known structures and devices are schematically shown in order to simplify the drawing.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used in the description herein and throughout the claims that follow, the source/drain can serve as a source or a drain. The first source/drain serves as the source when the second source/drain serves as the drain; in contrast, the second source/drain serves as the source when the first source/drain serves as the drain.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view of a non-volatile semiconductor device 100 according to one embodiment of the present disclosure. As shown in FIG. 1, the non-volatile semiconductor device 100 includes a gate dielectric layer 110, a floating gate 120, a coupling gate 130, a first source/drain 140 and a second source/drain 142.

The gate dielectric layer 110 is formed on a semiconductor substrate 150. The floating gate 120 is formed on the gate dielectric layer 110. The first source/drain 140 and the second source/drain 142 are formed in the semiconductor substrate 150 and disposed at opposing sides of the floating gate 120. The coupling gate 130 consists essentially of a capacitor dielectric layer 132 and a contact plug 134, wherein the capacitor dielectric layer 132 is formed on the floating gate 120, and the contact plug 134 is formed on the capacitor dielectric layer 132.

In this embodiment, the capacitor dielectric layer 132 is in continuous and direct contact with the floating gate 120 and the contact plug 134 and is disposed between the floating gate 120 and the contact plug 134. Moreover, the spacers 160 are disposed along the outside of the floating gate 120 and the gate dielectric layer 110.

In practice, the gate dielectric layer 110 may be preferably a high-K dielectric material, such as silicon oxide, silicon oxynitride, silicon nitride, an oxide, a nitrogen-containing oxide, a combination thereof, or the like. Preferably, the gate dielectric layer 110 has a relative permittivity value greater than about 4. Other examples of such materials include aluminum oxide, lanthanum oxide, hafnium oxide, zirconium oxide, hafnium oxynitride, or combinations thereof. The floating gate 120 may comprise a conductive material, such as a metal (e.g., tantalum, titanium, molybdenum, tungsten, platinum, aluminum, hafnium, or ruthenium), a metal silicide (e.g., titanium silicide, cobalt silicide, nickel silicide, or tantalum silicide), a metal nitride (e.g., titanium nitride or tantalum nitride), doped poly-crystalline silicon, other conductive materials, or a combination thereof.

In practice, a thickness of the capacitor dielectric layer 132 ranges from 50 Å to 400 Å. If the thickness of the capacitor dielectric layer 132 was less than 50 Å, the voltage breakdown of the capacitor dielectric layer 132 would easily occur, and electric charges would escape from the floating gate 120 through the capacitor dielectric layer 132. If the thickness of the capacitor dielectric layer 132 was greater than 400 Å, the electric coupling of the capacitor dielectric layer 132 would be poor.

In fabrication, the capacitor dielectric layer 132 is a self-aligned silicide blocking layer or a resist protective layer. The material of the capacitor dielectric layer 132 may be SiOx, SiOxNy, SixNy, other conductive materials, or a combination thereof.

The spacer 160 may be dielectric material, such as silicon oxide, silicon nitride, a combination thereof, or the like.

For operating the non-volatile semiconductor device 100, the coupling gate 130 can serve as a control gate. When this control gate, first source/drain 140, the second source/drain 142 and the semiconductor substrate 150 are applied to suitable voltages respectively for programming or erasing the non-volatile semiconductor device 100, the voltage applied to the coupling gate 130 couples to the floating gate 120, so that electrons can be trapped in the floating gate 120 through a way, such as the channel hot electron injection, or the electrons stored in the floating gate 120 can be pulled out through a way, such as the Fowler-Nordheim tunneling. In this embodiment, the coupling gate 130 is disposed for receiving a voltage and for coupling the voltage to the floating gate 120, so that electric charges of the floating gate 120 are injected or erased through the gate dielectric layer 110.

For manufacturing the conventional non-volatile memory devices, there is a need of complicated processes. For example, the fabrication of a double-polysilicon non-volatile memory needs additional and expensive processes, such as an additional doped polysilicon and an additional dielectric layer between the floating and the control gate. In this way, the additional processes introduce more thermal budgets and results in shifting of the characteristic of logic elements. However, an adjustment in the characteristic of logic elements delays the progress of production for a lot of time.

The contact plug 134 and the capacitor dielectric layer 132, such as the self-aligned silicide blocking layer or the resist protective layer, are manufactured through standard logic processes of semiconductor fabrication.

In the present invention, the material for the standard logic processes is utilized to manufacture the non-volatile semiconductor device without additional processes. Thus, the progress of production can be fast, and production costs can be reduced.

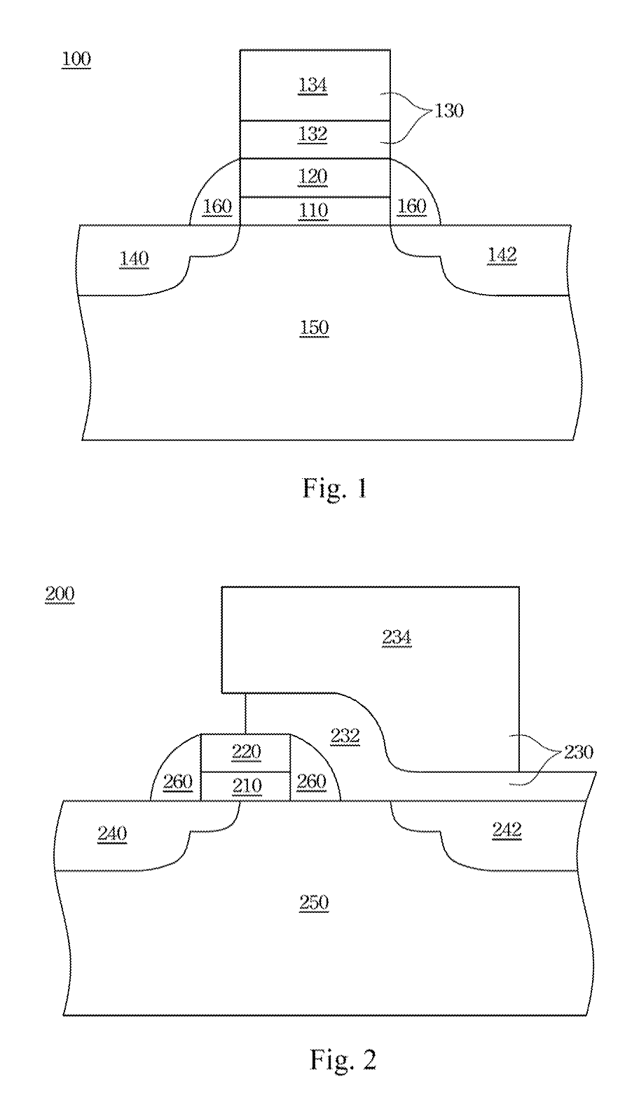

FIG. 2 is a cross-sectional view of a non-volatile semiconductor device 200 according to another embodiment of the present disclosure. As shown in FIG. 2, the non-volatile semiconductor device 200 includes a gate dielectric layer 210, a floating gate 220, a coupling gate 230, a first source/drain 240 and a second source/drain 242.

The gate dielectric layer 210 is formed on a semiconductor substrate 250. The floating gate 220 is formed on the gate dielectric layer 210. The first source/drain 240 and the second source/drain 242 are formed in the semiconductor substrate 250 and disposed at opposing sides of the floating gate 220. The coupling gate 230 consists essentially of a capacitor dielectric layer 232 and a contact plug 234, wherein the capacitor dielectric layer 232 is formed on the floating gate 220, and the contact plug 234 is formed on the capacitor dielectric layer 232.

In this embodiment, a distance from the coupling gate 220 to the first source/drain 240 is shorter than a distance from the coupling gate 220 to the second source/drain 242, and the capacitor dielectric layer 232 is in contact with a portion of the floating gate 220 and extends on the second source/drain 242. Moreover, the spacers 260 are disposed along the outside of the floating gate 220 and the gate dielectric layer 210.

In practice, the gate dielectric layer 210 may be preferably a high-K dielectric material, such as silicon oxide, silicon oxynitride, silicon nitride, an oxide, a nitrogen-containing oxide, a combination thereof, or the like. Preferably, the gate dielectric layer 210 has a relative permittivity value greater than about 4. Other examples of such materials include aluminum oxide, lanthanum oxide, hafnium oxide, zirconium oxide, hafnium oxynitride, or combinations thereof. The floating gate 220 may comprise a conductive material, such as a metal (e.g., tantalum, titanium, molybdenum, tungsten, platinum, aluminum, hafnium, or ruthenium), a metal silicide (e.g., titanium silicide, cobalt silicide, nickel silicide, or tantalum silicide), a metal nitride (e.g., titanium nitride or tantalum nitride), doped poly-crystalline silicon, other conductive materials, or a combination thereof.

The spacer 260 may be dielectric material, such as silicon oxide, silicon nitride, a combination thereof, or the like.

In practice, a thickness of the capacitor dielectric layer 232 ranges from 50 Å to 400 Å. If the thickness of the capacitor dielectric layer 232 was less than 50 Å, the voltage breakdown of the capacitor dielectric layer 232 would easily occur, and electric charges would escape from the floating gate 220 through the capacitor dielectric layer 232. If the thickness of the capacitor dielectric layer 232 was greater than 400 Å, the electric coupling of the capacitor dielectric layer 232 would be poor.

In fabrication, the capacitor dielectric layer 232 is a self-aligned silicide blocking layer or a resist protective layer. The material of the capacitor dielectric layer 232 may be SiOx, SiOxNy, SixNy, other conductive materials, or a combination thereof.

For operating the non-volatile semiconductor device 200, the coupling gate 130 can serve as a control gate. When this control gate, first source/drain 240, the second source/drain 242 and the semiconductor substrate 250 are applied to suitable voltages respectively for programming or erasing the non-volatile semiconductor device 200, the voltage applied to the coupling gate 230 couples to the floating gate 220, so that electrons can be trapped in the floating gate 220 through a way, such as the channel hot electron injection, or the electrons stored in the floating gate 220 can be pulled out through a way, such as the Fowler-Nordheim tunneling. In this embodiment, the coupling gate 230 is disposed for receiving a voltage and for coupling the voltage to the floating gate 220, so that electric charges of the floating gate 220 are injected or erased through the gate dielectric layer 210.

Technical advantages are generally achieved by means of the non-volatile semiconductor device 100 or 200, as follows:
1. LV Logic Process Compatible;
2. No Extra Mask or Thermal Cycles;
3. Min. Cell size;
4. Single poly process without double poly for making the control gate; and
5. Process cost will be minimized.

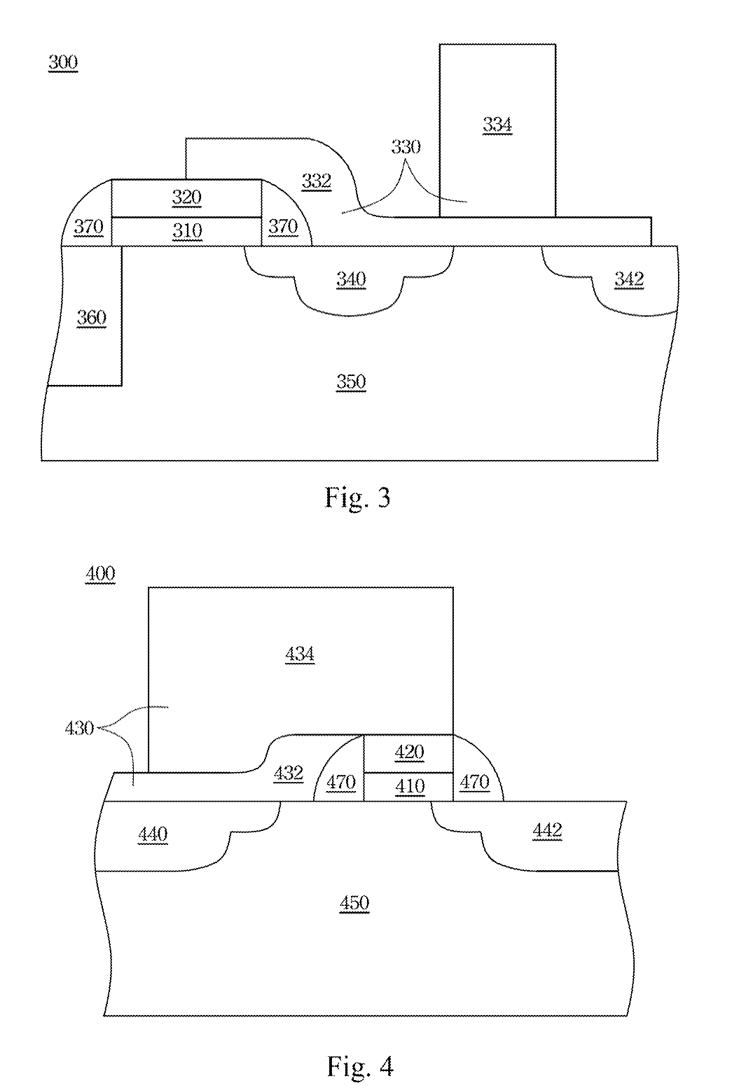

FIG. 3 is a cross-sectional view of a programmable memory device 300 according to one embodiment of the present disclosure. In this embodiment, the programmable memory device 300 can serves as one time or multi-times programmable memory device. As shown in FIG. 3, the programmable memory device 300 includes a gate dielectric layer 310, a polysilicon gate electrode 320, a coupling gate 330, a first source/drain 340 and a second source/drain 342.

The gate dielectric layer 310 is formed on a semiconductor substrate 350. The polysilicon gate electrode 320 is formed on the gate dielectric layer 310. The first source/drain 340 and the second source/drain 342 are formed in the semiconductor substrate 350 and are separate from each other. The coupling gate 330 consists essentially of a capacitor dielectric layer 332 and a contact plug 334, wherein the capacitor dielectric layer 332 is disposed on a portion of the semiconductor substrate 350, the portion of the semiconductor substrate 350 is positioned between the first source/drain 340 and the second source/drain 342, and the contact plug 334 is formed on the capacitor dielectric layer 332.

In the present embodiment, the programmable memory device 300 may further include a trench isolation structure 360. The trench isolation structure 360 is formed in the semiconductor substrate 350. The first source/drain 340 is positioned between the second source/drain 342 and the trench isolation structure 360, the trench isolation structure 360 and the first source/drain 340 are disposed at opposing sides of the polysilicon gate electrode 320, and the capacitor dielectric layer 342 is in contact with a portion of the polysilicon gate electrode 320 and extends on the second source/drain 342. Moreover, the spacers 370 are disposed along the outside of the polysilicon gate electrode 320 and the gate dielectric layer 310.

In practice, the gate dielectric layer 310 may be preferably a high-K dielectric material, such as silicon oxide, silicon oxynitride, silicon nitride, an oxide, a nitrogen-containing oxide, a combination thereof, or the like. Preferably, the gate dielectric layer 310 has a relative permittivity value greater than about 4. Other examples of such materials include aluminum oxide, lanthanum oxide, hafnium oxide, zirconium oxide, hafnium oxynitride, or combinations thereof. The polysilicon gate electrode 320 may comprise a conductive material, such as a metal (e.g., tantalum, titanium, molybdenum, tungsten, platinum, aluminum, hafnium, or ruthenium), a metal silicide (e.g., titanium silicide, cobalt silicide, nickel silicide, or tantalum silicide), a metal nitride (e.g., titanium nitride or tantalum nitride), doped poly-crystalline silicon, other conductive materials, or a combination thereof.

The spacers 370 may be dielectric material, such as silicon oxide, silicon nitride, a combination thereof, or the like.

In practice, a thickness of the capacitor dielectric layer 332 ranges from 50 Å to 400 Å. If the thickness of the capacitor dielectric layer 332 was less than 50 Å, the voltage breakdown of the capacitor dielectric layer 332 would easily occur. If the thickness of the capacitor dielectric layer 232 was greater than 400 Å, the electric coupling of the capacitor dielectric layer 232 would be poor.

In fabrication, the capacitor dielectric layer 332 is a self-aligned silicide blocking layer or a resist protective layer. The material of the capacitor dielectric layer 332 may be SiOx, SiOxNy, SixNy, other conductive materials, or a combination thereof.

A portion of the semiconductor substrate 350, the first source/drain 340, the second source/drain 342, the capacitor dielectric layer 332 and the contact plug 334 can construct an integrated CMOS device. In use, the contact plug 334 serves as a gate electrode; the capacitor dielectric layer 332 serves as a gate dielectric layer. One of the first source/drain 340 and the second source/drain 342 serves as a source, and the other serves as a drain. The semiconductor substrate 350 is disposed under the first source/drain 340, the second source/drain 342, the capacitor dielectric layer 332 and the contact plug 334. In other words, a select transistor consists essentially of the portion of the semiconductor substrate 350, the first source/drain 340, the second source/drain 342, the capacitor dielectric layer 332 and the contact plug 334. One or more select transistors can be configured in a non-volatile memory device in wide use. The voltages can be applied to a certain of cells of the memory device selectively by means of the select transistors.

For operating the programmable memory device 300, the coupling gate 330 can serve as a select gate. When this select gate, first source/drain 340, the second source/drain 342 and the semiconductor substrate 350 are applied to suitable voltages respectively for programming the programmable memory device 300, an oxide breakdown of the gate dielectric layer 310 can occur, wherein the oxide breakdown results from the high voltage transmitted to the polysilicon gate electrode 320.

FIG. 4 is a cross-sectional view of a programmable memory device 400 according to another embodiment of the present disclosure. In this embodiment, the programmable memory device 400 can serves as one time or multi-times programmable memory device. As shown in FIG. 4, the programmable memory device 400 includes a gate dielectric layer 410, a polysilicon gate electrode 420, a coupling gate 430, a first source/drain 440 and a second source/drain 442.

The gate dielectric layer 410 is formed on a semiconductor substrate 450. The polysilicon gate electrode 420 is formed on the gate dielectric layer 410. The first source/drain 440 and the second source/drain 442 are formed in the semiconductor substrate 450 and are separate from each other. The coupling to gate 330 consists essentially of a capacitor dielectric layer 332 and a contact plug 434, wherein the capacitor dielectric layer 432 is disposed on a portion of the semiconductor substrate 450, the portion of the semiconductor substrate 450 is positioned between the first source/drain 440 and the second source/drain 442, and the contact plug 434 is formed on the capacitor dielectric layer 432.

In the present embodiment, the gate dielectric layer 410 is in partial contact with the second source/drain 442, the capacitor dielectric layer 432 is disposed along a side of the polysilicon gate electrode 420, and the contact plug 434 is in direct contact with the capacitor dielectric layer 432. Moreover, the spacers 470 are disposed along the outside of the polysilicon gate electrode 420 and the gate dielectric layer 410.

In practice, the gate dielectric layer 410 may be preferably a high-K dielectric material, such as silicon oxide, silicon oxynitride, silicon nitride, an oxide, a nitrogen-containing oxide, a combination thereof, or the like. Preferably, the gate dielectric layer 410 has a relative permittivity value greater than about 4. Other examples of such materials include aluminum oxide, lanthanum oxide, hafnium oxide, zirconium oxide, hafnium oxynitride, or combinations thereof. The polysilicon gate electrode 420 may comprise a conductive material, such as a metal (e.g., tantalum, titanium, molybdenum, tungsten, platinum, aluminum, hafnium, or ruthenium), a metal silicide (e.g., titanium silicide, cobalt silicide, nickel silicide, or tantalum silicide), a metal nitride (e.g., titanium nitride or tantalum nitride), doped poly-crystalline silicon, other conductive materials, or a combination thereof.

The spacers 470 may be dielectric material, such as silicon oxide, silicon nitride, a combination thereof, or the like.

In practice, a thickness of the capacitor dielectric layer 432 ranges from 50 Å to 400 Å. If the thickness of the capacitor dielectric layer 432 was less than 50 Å, the voltage breakdown of the capacitor dielectric layer 432 would easily occur. If the thickness of the capacitor dielectric layer 432 was greater than 400 Å, the electric coupling of the capacitor dielectric layer 432 would be poor.

In fabrication, the capacitor dielectric layer 432 is a self-aligned silicide blocking layer or a resist protective layer. The material of the capacitor dielectric layer 432 may be SiOx, SiOxNy, SixNy, other conductive materials, or a combination thereof.

For operating the programmable memory device 400, the coupling gate 430 can serve as a select gate. When this select gate, first source/drain 440, the second source/drain 442 and the semiconductor substrate 450 are applied to suitable voltages respectively for programming the programmable memory device 400, an oxide breakdown of the gate dielectric layer 410 can occur, wherein the oxide breakdown results from the high voltage transmitted to the polysilicon gate electrode 420.

Technical advantages are generally achieved by means of the programmable memory device 300 or 400, as follows:
1. LV Logic Process Compatible;
2. No Extra Mask or Thermal Cycles for making the select gate;
3. Min. Cell size;
4. Single poly process without double poly for making the control gate; and
5. Process cost will be minimized.

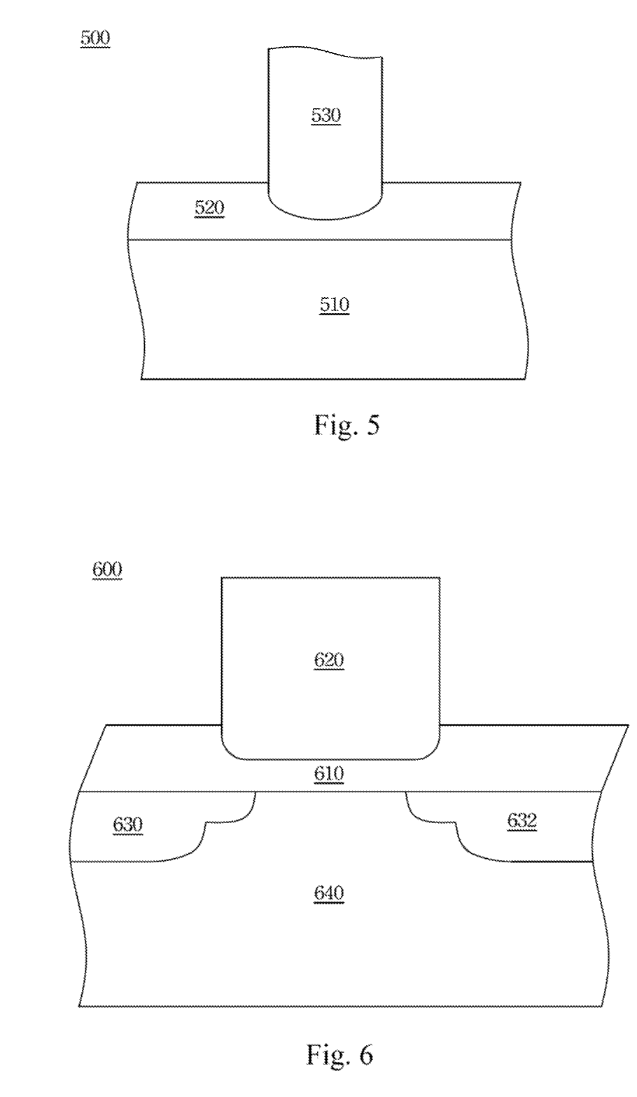

FIG. 5 is a cross-sectional view of a capacitor 500 according to one embodiment of the present disclosure. As shown in FIG. 5, the capacitor 500 includes a bottom electrode 510, a capacitor dielectric layer 520 and a top electrode 530.

The bottom electrode 510 is a heavily doped polysilicon layer or a heavily doped region of a semiconductor substrate. The bottom electrode 510 is a heavily doped polysilicon layer or a heavily doped region of a semiconductor substrate. The capacitor dielectric layer 520 is formed on the bottom electrode 510. The top electrode 530 is formed on the capacitor dielectric layer 520, wherein the capacitor dielectric layer 520 is a self-aligned silicide blocking layer or a resist protective layer.

In the present embodiment, as to the bottom electrode 510, the heavily doped polysilicon layer is an n-type heavily doped polysilicon layer; the heavily doped region of the semiconductor substrate is an n-type heavily doped region of the semiconductor substrate. Moreover, the top electrode 530 is a contact plug that is in direct contact with the capacitor dielectric layer 520.

In practice, a thickness of the capacitor dielectric layer 520 ranges from 50 Å to 400 Å. If the thickness of the capacitor dielectric layer 520 was less than 50 Å, the voltage breakdown of the capacitor dielectric layer 520 would easily occur. If the thickness of the capacitor dielectric layer 520 was greater than 400 Å, the capacitance of the capacitor 500 would not be enough to use.

In fabrication, the capacitor dielectric layer 520 is a self-aligned silicide blocking layer or a resist protective layer. The material of the capacitor dielectric layer 520 may be SiOx, SiOxNy, SixNy, other conductive materials, or a combination thereof.

When the capacitor 500 is utilized, the bottom electrode 510 and the top electrode 530 are applied to suitable voltages, so that electric charges can be stored in the capacitor dielectric layer 520.

Technical advantages are generally achieved by means of the capacitor 500, as follows:
1. CMOS Logic Process Compatible;
2. Compared with a conventional metal-insulator-metal (MIM) capacitor, the capacitor 500 is made without an additional metal layer serving as a bottom electrode; and
3. Compared with a conventional metal-insulator-metal (MIM) capacitor, the capacitor 500 is made without an additional ONO.

FIG. 6 is a cross-sectional view of a metal oxide semiconductor 600 according to one embodiment of the present disclosure. As shown in FIG. 6, the metal oxide semiconductor 600 includes a capacitor dielectric layer 610, a contact plug 620, a first source/drain 630 and a second source/drain 632.

The capacitor dielectric layer 610 is formed on a semiconductor substrate 640. The contact plug 620 is formed on the capacitor dielectric layer 610. The first source/drain 630 and the second source/drain 632 are formed in the semiconductor substrate 640 and disposed at opposing sides of the contact plug 620. Moreover, the cross section of the contact plug 620 may be superimposed over a portion of the first and second source/drains 630 and 632.

In the present embodiment, the first source/drain 630 is a source, and the second source/drain 632 is a drain, wherein the drain is a n-type well, a p-type well or a lightly doped drain.

In practice, a thickness of the capacitor dielectric layer 610 ranges from 50 Å to 400 Å. If the thickness of the capacitor dielectric layer 610 was less than 50 Å, the voltage breakdown of the capacitor dielectric layer 610 would easily occur. If the thickness of the capacitor dielectric layer 610 was greater than 400 Å, the electric coupling of the metal oxide semiconductor 600 would be poor.

Moreover, a distance between the first source/drain 630 and the second source/drain 632 ranges from 0.18 μm to 1 μm. If the distance between the first source/drain 630 and the second source/drain 632 was less than 0.18 μm, the leakage current between the first source/drain 630 and the second source/drain 632 easily occur. If the distance between the first source/drain 630 and the second source/drain 632 was greater than 1 μm, the channel current would be poor.

In fabrication, the capacitor dielectric layer 610 is a self-aligned silicide blocking layer or a resist protective layer. The material of the capacitor dielectric layer 610 may be SiOx, SiOxNy, SixNy, other conductive materials, or a combination thereof. For operating the metal oxide semiconductor 600, the contact plug 620 can serve as a gate electrode, and the capacitor dielectric layer 610 can serve as a gate dielectric layer. When this gate electrode, the first source/drain 630, the second source/drain 632 and the semiconductor substrate 640 are applied to suitable voltages, the metal oxide semiconductor 600 can be turned on or cut off.

The metal oxide semiconductor 600 is a high voltage device structurally. The conventional high voltage device needs a very thick gate dielectric layer. However, the fabrication of this thick gate dielectric layer introduces more thermal budgets and the etching process. The contact plug 620 and the capacitor dielectric layer 610, such as the self-aligned silicide blocking layer or the resist protective layer, are manufactured through standard logic processes of semiconductor fabrication. In the present invention, the material for the standard logic processes is utilized to manufacture the non-volatile semiconductor device without additional processes. Thus, the progress of production can be fast, and production costs can be reduced.

The self-aligned silicide blocking layer, the resist protective oxide layer or the contact process can be adjusted for making the capacitor dielectric layer 610 thick enough, so that the gate electrode 620 can receive high voltage. In addition, the first source/drain 630 and the second source/drain 632 each may be a deeper n-type well that is lightly doped ions or a deeper p-type well that is lightly doped ions, so that the first source/drain 630 and the second source/drain 632 can further receive high voltage. Thus, the high voltage device with the voltage-withstand gate, source and drain is accomplished.

Technical advantages are generally achieved by means of the metal oxide semiconductor 600, as follows:
1. CMOS Logic Process Compatible;
2. No Extra Mask or Thermal Cycles for making the gate electrode; and
3. The capacitor dielectric layer 610 serves as a gate dielectric layer with high-gated breakdown.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

What is claimed is:

1. A non-volatile semiconductor device comprising:
a gate dielectric layer formed on a semiconductor substrate;
a floating gate formed on the gate dielectric layer;
a first source/drain and a second source/drain formed in the semiconductor substrate and disposed at opposing sides of the floating gate; and
a coupling gate consisting essentially of a capacitor dielectric layer and a contact plug, wherein the capacitor dielectric layer is formed on the floating gate, and the contact plug is formed on the capacitor dielectric layer.

2. The non-volatile semiconductor device of claim 1, wherein the capacitor dielectric layer is a self-aligned silicide blocking layer or a resist protective layer.

3. The non-volatile semiconductor device of any one of claims 1-2, wherein the capacitor dielectric layer is a material selected from the group consisting of SiOx, SiOxNy and SixNy.

4. The non-volatile semiconductor device of claim 1, wherein a thickness of the capacitor dielectric layer ranges from 50 Å to 400 Å.

5. The non-volatile semiconductor device of claim 1, wherein the capacitor dielectric layer is in continuous and direct contact with the floating gate and the contact plug and is disposed between the floating gate and the contact plug.

6. The non-volatile semiconductor device of claim 1, wherein a distance from the coupling gate to the first source/drain is shorter than a distance from the coupling gate to the second source/drain, and the capacitor dielectric layer is in contact with a portion of the floating gate and extends on the second source/drain.

7. The non-volatile semiconductor device of claim 1, wherein the coupling gate is disposed for receiving a voltage and for coupling the voltage to the floating gate, so that electric charges of the floating gate are injected or erased through the gate dielectric layer.

8. A programmable memory device comprising:
a gate dielectric layer formed on a semiconductor substrate;
a polysilicon gate electrode formed on the gate dielectric layer for receiving a voltage, so that a dielectric breakdown of the gate dielectric layer results from the voltage for accessing data;
a first source/drain and a second source/drain formed in the semiconductor substrate and being separate from each other; and
a coupling gate consisting essentially of a capacitor dielectric layer and a contact plug, wherein the capacitor dielectric layer is disposed on a portion of the semiconductor substrate, the portion of the semiconductor substrate is positioned between the first source/drain and the second source/drain, and the contact plug is formed on the capacitor dielectric layer.

9. The programmable memory device of claim 8, wherein the capacitor dielectric layer is a self-aligned silicide blocking layer or a resist protective layer.

10. The programmable memory device of any one of claims 8-9, wherein the capacitor dielectric layer is a material selected from the group consisting of SiOx, SiOxNy and SixNy.

11. The programmable memory device of claim 8, wherein a thickness of the capacitor dielectric layer ranges from 50 Å to 400 Å.

12. The programmable memory device of claim 8, further comprising:
a trench isolation structure formed in the semiconductor substrate,
wherein the first source/drain is positioned between the second source/drain and the trench isolation structure, the trench isolation structure and the first source/drain are disposed at opposing sides of the polysilicon gate electrode, and the capacitor dielectric layer is in contact with a portion of the polysilicon gate electrode and extends on the second source/drain.

13. The programmable memory device of claim 8, wherein the gate dielectric layer is in partial contact with the second source/drain, the capacitor dielectric layer is disposed along a side of the polysilicon gate electrode, and the contact plug is in direct contact with the capacitor dielectric layer.

14. A capacitor compatible with semiconductor fabrication, the capacitor comprising:
a bottom electrode being a heavily doped polysilicon layer or a heavily doped region of a semiconductor substrate;
a capacitor dielectric layer formed on the bottom electrode; and
a top electrode formed on the capacitor dielectric layer,
wherein the capacitor dielectric layer is a self-aligned silicide blocking layer or a resist protective layer.

15. The capacitor of claim 14, wherein the capacitor dielectric layer is a material selected from the group consisting of SiOx, SiOxNy and SixNy.

16. The capacitor of claim 14, wherein a thickness of the capacitor dielectric layer ranges from 50 Å to 400 Å.

17. The capacitor of claim 14, wherein the heavily doped polysilicon layer is an n-type heavily doped polysilicon layer, and the heavily doped region of the semiconductor substrate is an n-type heavily doped region of the semiconductor substrate.

18. The capacitor of claim 14, wherein the top electrode is a contact plug that is in direct contact with the capacitor dielectric layer.

19. A metal oxide semiconductor compatible with semiconductor fabrication, the metal oxide semiconductor comprising:
a capacitor dielectric layer formed on a semiconductor substrate;
a contact plug formed on the capacitor dielectric layer; and
a first source/drain and a second source/drain formed in the semiconductor substrate and disposed at opposing sides of the contact plug.

20. The metal oxide semiconductor of claim 19, wherein the capacitor dielectric layer is a self-aligned silicide blocking layer or a resist protective layer.

21. The metal oxide semiconductor of any one of claims 19-20, wherein the capacitor dielectric layer is a material selected from the group consisting of SiOx, SiOxNy and SixNy.

22. The metal oxide semiconductor of claim 19, wherein a thickness of the capacitor dielectric layer ranges from 50 Å to 400 Å.

23. The metal oxide semiconductor of claim 19, wherein a distance between the first source/drain and the second source/drain ranges from 0.18 μm to 1 μm.

24. The metal oxide semiconductor of claim 19, wherein the first source/drain is a source, and the second source/drain is a drain, wherein the drain is a n-type well, a p-type well or a lightly doped drain.
